(19) United States
(12) Patent Application Publication
(10) Pub. No.: US 2016/0073552 A1
(43) Pub. Date: Mar. 10, 2016

(54) Heat dissipation structure for electronic device

(71) Applicant: Shen-An Hsu, Kaohsiung (TW)

(72) Inventor: Shen-An Hsu, Kaohsiung (TW)

(21) Appl. No.: 14/941,645

(22) Filed: Nov. 15, 2015

(30) Foreign Application Priority Data
Aug. 3, 2015 (TW) 104212452

(51) Int. Cl. H05K 7/20

(52) U.S. Cl. CPC H05K 7/20418

(57) ABSTRACT

A heat dissipation structure for an electronic device is adhered on the electronic device to conduct heat dissipation. The heat dissipation structure includes at least one heat dissipation structure element. Each heat dissipation structure element includes a high thermal conductivity material element and a thermal conductivity insulating medium which is disposed between the high thermal conductivity material element and outside area to provide insulation and thermal conductivity function. The thermal conductivity insulating medium is made of a combination of ceramic and polymers. The thermal conductivity insulating medium has an additional heat conductivity effect of a third dimensional heat dissipation that replaces the thin strip made of PET, manufactured as “Mylar”, widely used in the electronic components for insulation. The heat dissipation area is increased greatly and a high efficient heat dissipation effect is achieved.

### BACKGROUND OF THE INVENTION

1. Field of the Invention

The invention relates to an improved heat dissipation structure for an electronic device and more particularly to an improvement of insulating material used in the heat dissipation structure of an electronic device.

2. Description of Related Art

In terms of the heat dissipation structure of an electronic device, graphite sheets are typically used as the key high thermal conductivity material elements for heat dissipation due to its excellent effect on surface heat dissipation recently. However, if the high thermal conductivity material elements made of graphite material are used for the purpose of discharging thermal heat generated during the operation of electronic components, the setting of the high thermal conductivity material elements and the electronic device must be very close to each other. Nevertheless, taking the graphite as an example, graphite not only has high thermal conductivity but also is a high electrical conductivity material. If graphite material is installed close to various types of electronic components or there is no protection device with insulating effect installed between the graphite material and the outer environment, it is likely to cause short circuits to the electronic components. Therefore, the insulating medium used in the market currently is a thin strip made of a type of PET material (MYLAR) mostly. Thin strips made of PET material (MYLAR) can be extremely thin in thickness. Through the using this type of thin strips, insulation isolation effect can be obtained between the thin graphite sheets and the outside environment or the electronic device. Nevertheless, the PET material (MYLAR) itself has very little thermal conductive effect and can not provide heat dissipation effect for the high thermal conductivity material.

Regarding the conventional heat dissipation structure for electronic devices, please refer to FIG. 1 and FIG. 2 at the same time. FIG. 1 is a schematic sectional view of a conventional heat dissipation structure and FIG. 2 is a view of the direction of thermal energy transmitted in the conventional heat dissipation structure.

In FIG. 1, a heat dissipation structure that is typically used is presented. The heat dissipation structure 1 and the electronic device 2 are joined together using an adhesive medium 3 whereas the heat dissipation structure 1 comprises a high thermal conductivity material element 11 (such as the graphite sheet) and a conventional insulating medium 12 (such as the PET material).

However, the conventional insulating medium 12 can not provide the effect of thermal conductivity and heat dissipation. Therefore, the function of the heat dissipation that is exerted in the high thermal conductivity material element 11 comes to a halt at its boundary since there is no heat dissipation channel to continue such function thereafter. The direction of thermal energy emitted by the electronic device He progresses from the electronic device 2 to the adhesive medium 3 that has thermal conductivity; the thermal energy emitted by the electronic device is continuously forwarded in the direction of thermal energy transmitted in the adhesive medium Ht to the high thermal conductivity material element 11. At this point, the high thermal conductivity material element 11 of this example diffuses the thermal energy through the two dimensional mode of surface heat dissipation, as illustrated in the diagram of the direction of thermal energy transmitted in graphite Hg diffuses in a horizontal direction.

Thus, the need for improvement still exists.

### SUMMARY OF THE INVENTION

It is therefore one object of the invention to provide a heat dissipation structure for an electronic device that is adhered on the electronic device to conduct heat dissipation wherein the heat dissipation structure comprises at least one heat dissipation structure element; each of the heat dissipation structure element includes the high thermal conductivity material element and thermal conductivity insulating medium which is disposed between the high thermal conductivity material element and outside area to provide insulation and thermal conductivity function; the thermal conductivity insulating medium is composed of a combination of ceramic and polymers.

The above and other objects, features and advantages of the invention will become apparent from the following detailed description taken with the accompanying drawings.

### BRIEF DESCRIPTION OF THE DRAWINGS

FIG. 1 is a schematic sectional view of a conventional heat dissipation structure;

FIG. 2 is a view of the direction of thermal energy transmitted in the conventional heat dissipation structure;

FIG. 3 is a perspective composite view of a first preferred embodiment of the invention;

FIG. 3A is a detailed view of the area A in FIG. 3;

FIG. 4 is a perspective exploded view of the first preferred embodiment of the invention;

FIG. 5 is a view of the direction of thermal energy transmitted in the first preferred embodiment of the invention;

FIG. 6 is a perspective exploded view of a second preferred embodiment of the invention;

FIG. 7 is a perspective exploded view of a third preferred embodiment of the invention;

FIG. 8 is a perspective exploded view of a fourth preferred embodiment of the invention;

FIG. 9 is a perspective composite view of a fifth preferred embodiment of the invention;

FIG. 9A is a detailed view of the area A in FIG. 9;

FIG. 10 is a perspective exploded view of the fifth preferred embodiment of the invention;

FIG. 11 is a view of the direction of thermal energy transmitted in the heat dissipation structure of the fifth preferred embodiment of the invention;

FIG. 12 is a structural view of a single layer heat dissipation circuit board of a sixth preferred embodiment of the invention; and

FIG. 13 is a structural view of a multilayer heat dissipation circuit board of a seventh preferred embodiment of the invention.

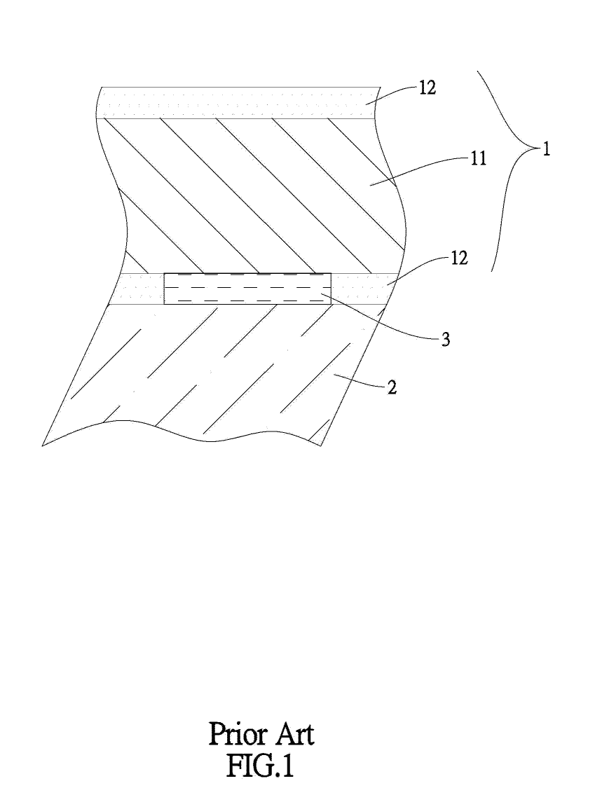

### DETAILED DESCRIPTION OF THE INVENTION

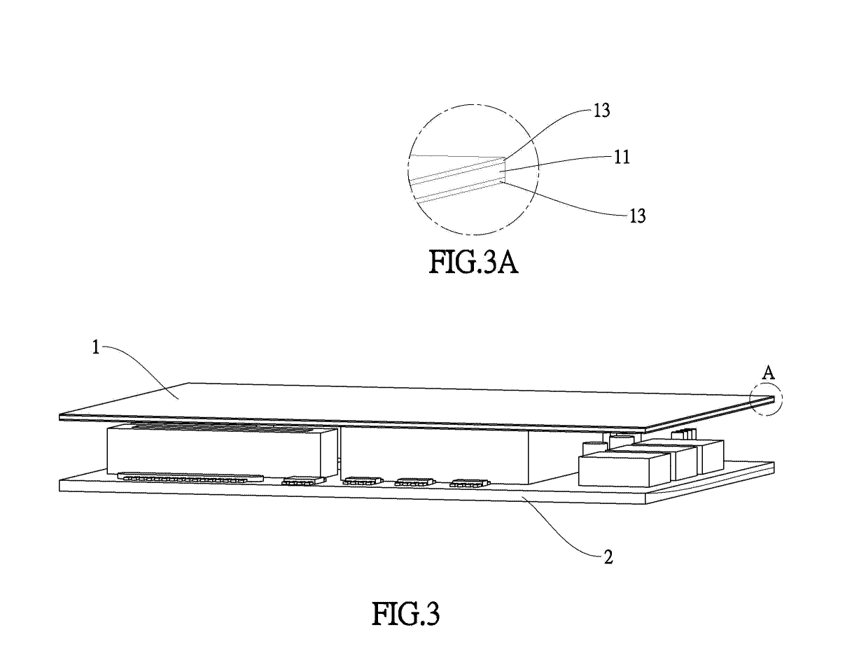

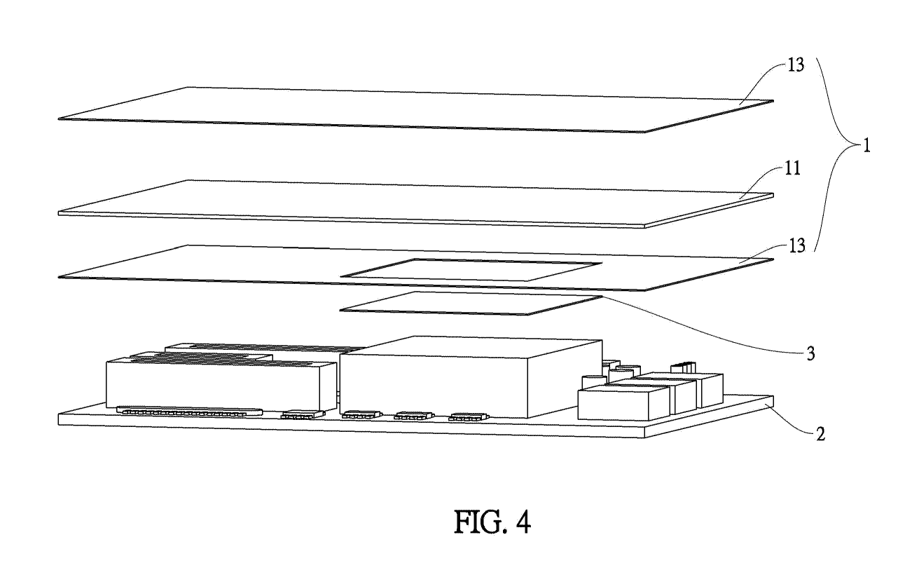

Please refer to FIG. 3 to FIG. 5 together for the explanation of a first preferred embodiment of the invention. According to FIG. 3, the heat dissipation structure 1 that comprises the high thermal conductivity material element 11, which provides the insulation protection and has the thermal conductivity insulating medium 13 adhered on both top and bottom thereof, is joined onto the electronic device 2. According to FIG. 4, the method used in the first preferred embodiment of the heat dissipation structure 1 of the invention is to join the high thermal conductivity material element 11 onto the electronic device 2 using the adhesive medium 3. In addition, space that is not used by the adhesive medium 3 on both sides of the high thermal conductivity material element 11 is applied with the thermal conductivity insulating medium 13 so that there are insulation protection between the high thermal conductivity material element 11 and outer space and the electronic device 2. No electrical signal short circuit will occur due to electrical conduction.

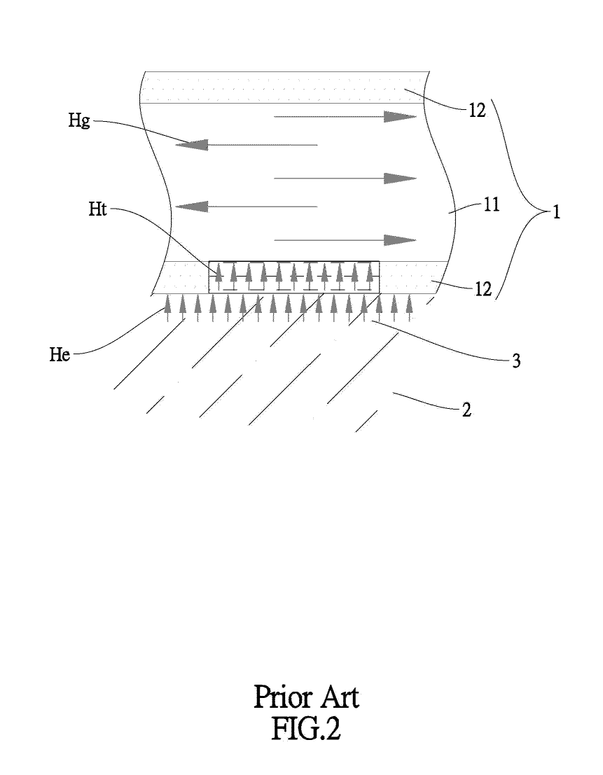

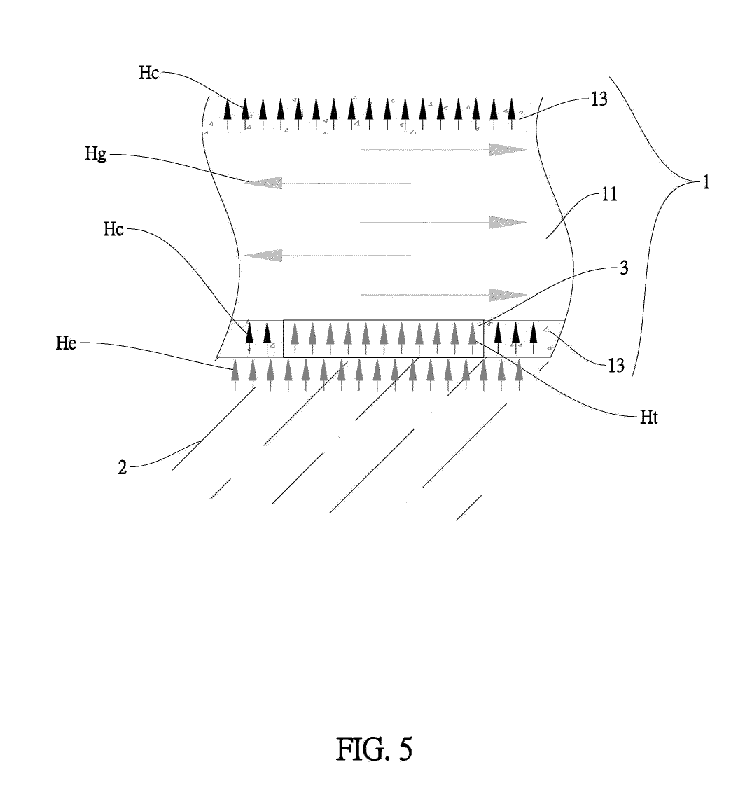

Comparing FIG. 5 and the direction of thermal conduction of the conventional heat dissipation structure in FIG. 2, it is obvious that the directions of thermal conduction in the first embodiment has an additional direction of thermal energy transmitted in the thermal conductivity insulating medium Hc. In other words, when the electronic device 2 generates thermal energy during its operation, the direction of thermal energy emitted by the electronic device He progresses from the electronic device 2 to the adhesive medium 3, which has thermal conductivity, and the thermal conductivity insulating medium 13. The thermal energy emitted by the electronic device is continuously forwarded in the direction of thermal energy transmitted in the adhesive medium Ht and the direction of thermal energy transmitted in the thermal conductivity insulating medium Hc to the high thermal conductivity material element 11 of the heat dissipation structure 1. At this moment, the high thermal conductivity material element 11 of the invention (such as the graphite sheet) diffuses thermal energy through the two dimensional mode of surface heat dissipation as illustrated in the diagram, along the direction of thermal energy transmitted in graphite Hg in a horizontal direction. Afterward, the thermal energy continuously passes through the thermal conductivity insulating medium 13 joined on the top of the high thermal conductivity material element 11 and diffuses outward in the direction of thermal energy transmitted in the thermal conductivity insulating medium Hc.

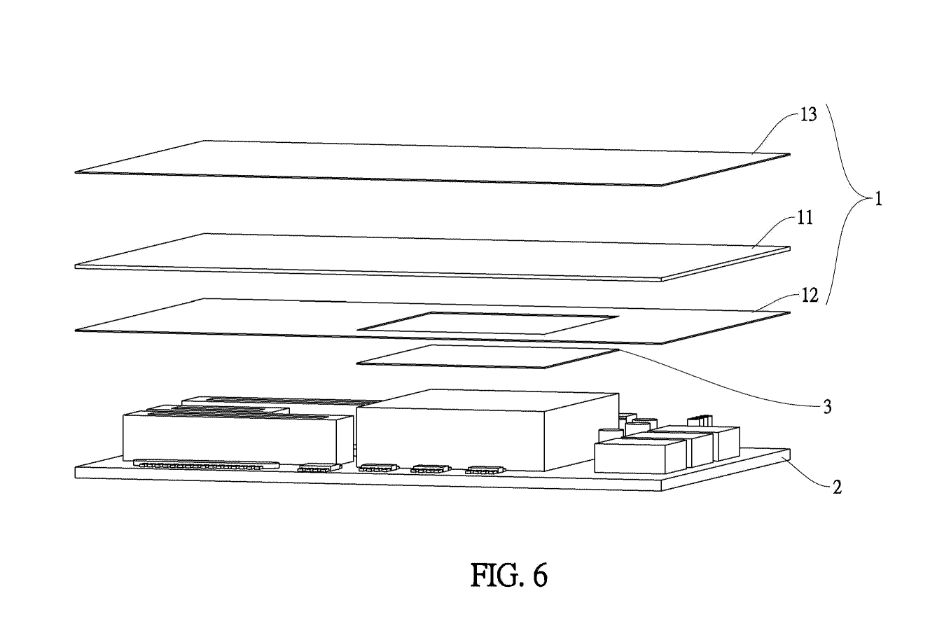

Please refer to FIG. 6 for the explanation of a second preferred embodiment of the invention. According to FIG. 6, the method used in the second preferred embodiment of the heat dissipation structure 1 described in the invention is to join the high thermal conductivity material element 11 onto the electronic device 2 using the adhesive medium 3. In addition, space that is not used by the adhesive medium 3 on one side of the high thermal conductivity material element 11 close to the electronic device 2 is applied with the conventional insulating medium 12; the other side facing outward is applied with the thermal conductivity insulating medium 13 so that there are insulation protection between the high thermal conductivity material element 11 and outer space and the electronic device 2. No electrical signal short circuit will occur due to electrical conduction.

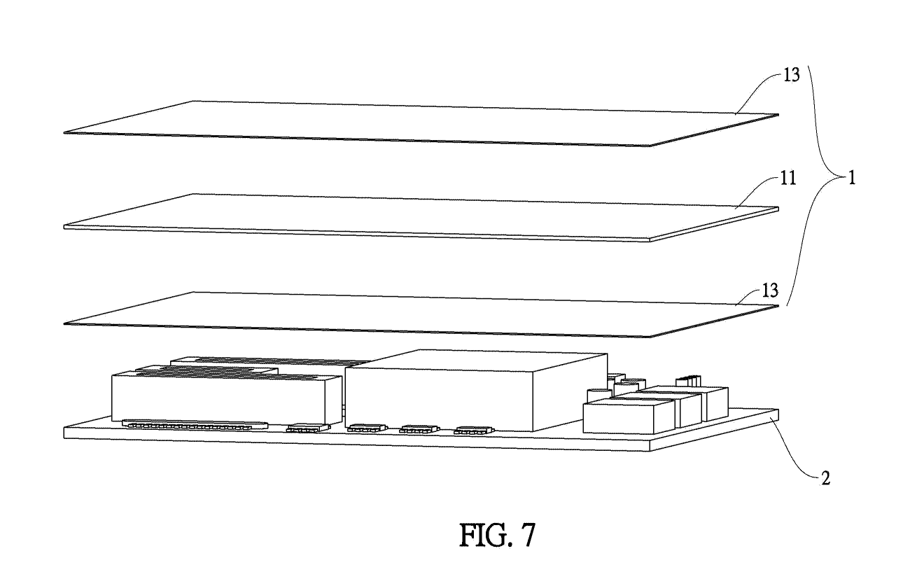

Please refer to FIG. 7 for the explanation of a third preferred embodiment of the invention. According to FIG. 7, the heat dissipation structure 1 comprising the high thermal conductivity material element 11 and the thermal conductivity insulating medium 13 adhered to both sides thereof does not need to use the adhesive medium 3 described in the first embodiment and the second embodiment (please refer to FIG. 4 and FIG. 6) and is adhered onto the electronic device 2 through the adhesion of the material containing polymers instead. In other words, in the heat dissipation structure 1 of the third embodiment, both sides of the high thermal conductivity material element 11 are joined with the thermal conductivity insulating medium 13 so that the structure not only provides effective thermal conductivity and insulation but only allows the element to be joined onto the electronic device through the self adhesion feature.

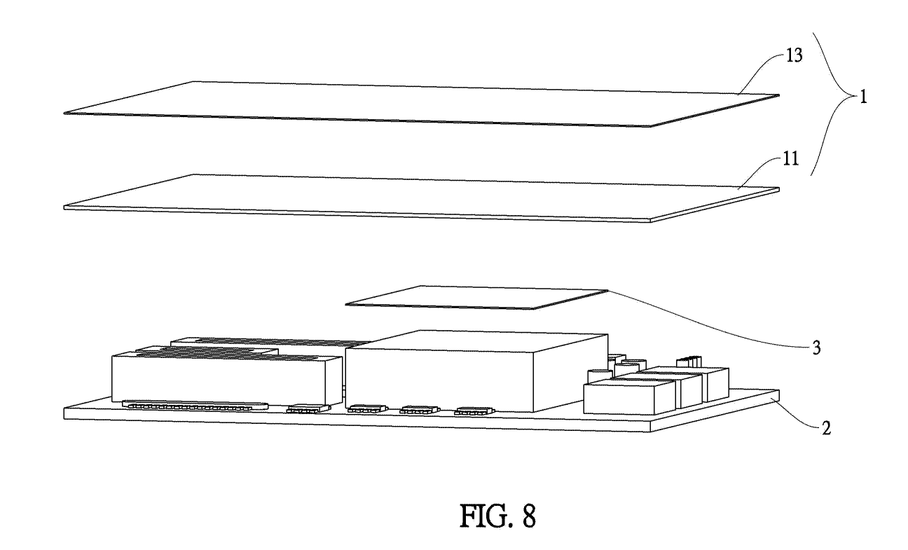

Please refer to FIG. 8 for the explanation of a fourth preferred embodiment of the invention. According to FIG. 8, the heat dissipation structure 1 comprises the high thermal conductivity material element 11 having one side of the high thermal conductivity material element 11 facing outward to be joined with the thermal conductivity insulating medium 13. The heat dissipation structure is adhered directly onto the electronic device 2 through the adhesive medium 3 to prevent impact to the electronic device 2 from the outer electromagnetic waves resulting in short circuits or reduction on effectiveness. The heat dissipation effect can increase due to the thermal conductivity of the thermal conductivity insulating medium 13.

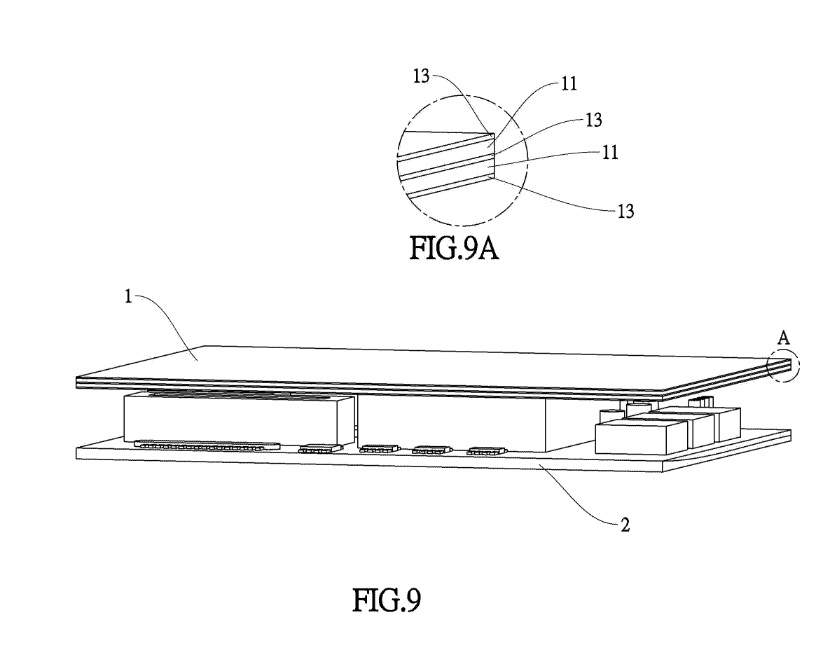

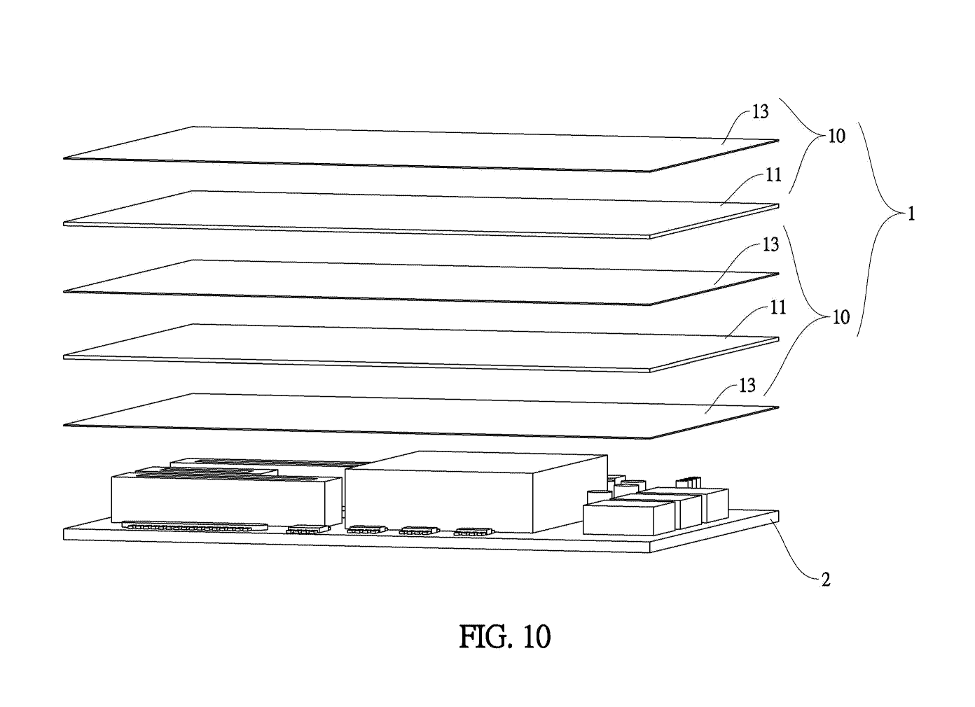

Please refer to FIG. 9 to FIG. 11 for the explanation of a fifth preferred embodiment of the invention. In this preferred embodiment of the invention, the heat dissipation structure 1 uses the high thermal conductivity material element 11 as the main body for heat dissipation. Therefore, every single high thermal conductivity material element 11 and the thermal conductivity insulating medium 13 or the conventional insulating medium 12, which is joined onto one side or both sides thereof (please refer to FIG. 6), can be viewed as one heat dissipation structure element 10. In the fifth embodiment, the heat dissipation structure element 10 and other heat dissipation structure element 10 are joined together through the use of the thermal conductivity and self adhesion of the thermal conductivity insulating medium 13 applied in between the heat dissipation structure elements so that the elements can be stacked up together to form a heat dissipation structure 1. Thus the heat dissipation effect increases after the heat dissipation structure 1 is joined with the electronic device 2.

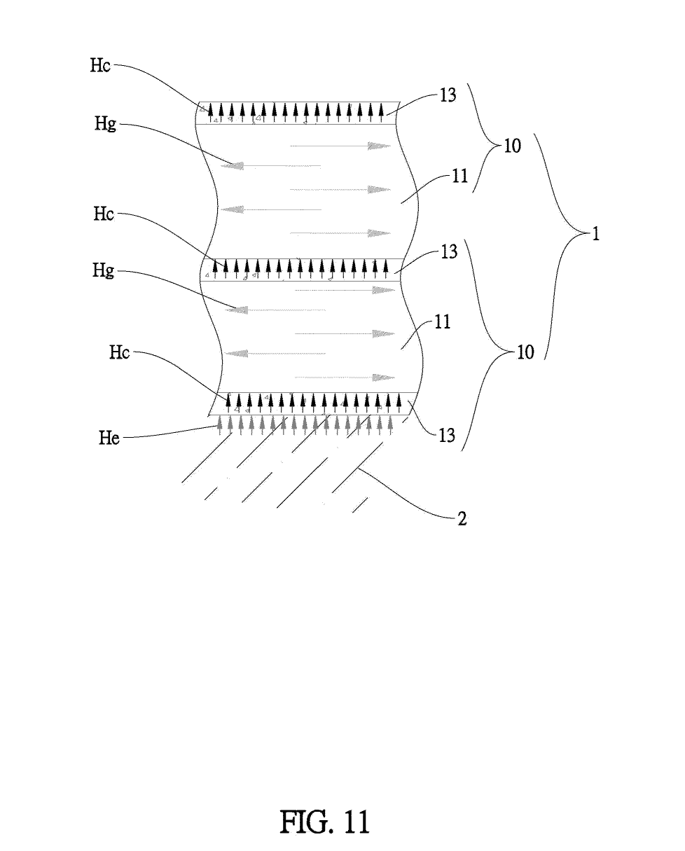

Please refer to FIG. 11, this is a view of the direction of thermal energy transmitted in the heat dissipation structure of the fifth preferred embodiment of the invention. As illustrated in the figure, the direction of thermal energy emitted by the electronic device He progresses from the electronic device 2 to the thermal conductivity insulating medium 13 wherein the thermal conductivity insulating medium 13 provides heat dissipation in the vertical direction. In other words, the direction of thermal energy transmitted in the thermal conductivity insulating medium Hc forwards the thermal energy emitted from the electronic device to the high thermal conductivity material element 11 through the thermal conductivity insulating medium 13. At this point, the high thermal conductivity material element 11 of this example diffuses the thermal energy in the surface heat dissipation mode along the direction of thermal energy transmitted in graphite Hg and progresses in a horizontal direction. At the same time, through the thermal conductivity insulting medium 13 on the other side the high thermal conductivity material element 11, the thermal energy progresses in the direction of thermal energy transmitted in the thermal conductivity insulating medium Hc in the vertical direction to the next high thermal conductivity material element 11 so that the second piece of high thermal conductivity material element 11 transmits the thermal energy in a surface heat dissipation mode along the direction of thermal energy transmitted in graphite horizontally. Last, the thermal energy passes through the thermal conductivity insulating medium 13 and is emitted vertically to outside areas.

The practical applications of the invention can be joined with the circuit boards, so that the circuit boards have the thermal conductivity feature. The specific implementation is to use a single heat dissipation structure element 10 or two or more heat dissipation structure element 10 and cooper foil (circuit) 2′ in order to compose or press into a thermal conductivity circuit board that has thermal conductivity, as explained in the sixth embodiment and the seventh preferred embodiment of the invention.

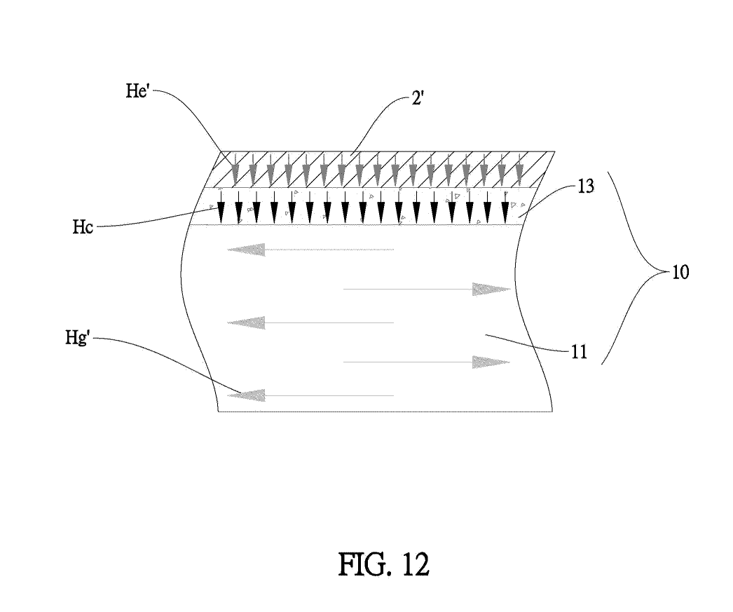

Please refer to FIG. 12, a sixth preferred embodiment of the invention is a structure of a “single layer thermal conductivity circuit board” comprising a single heat dissipation structure element 10 and cooper foil (circuit) 2′ that are composed and pressed together.

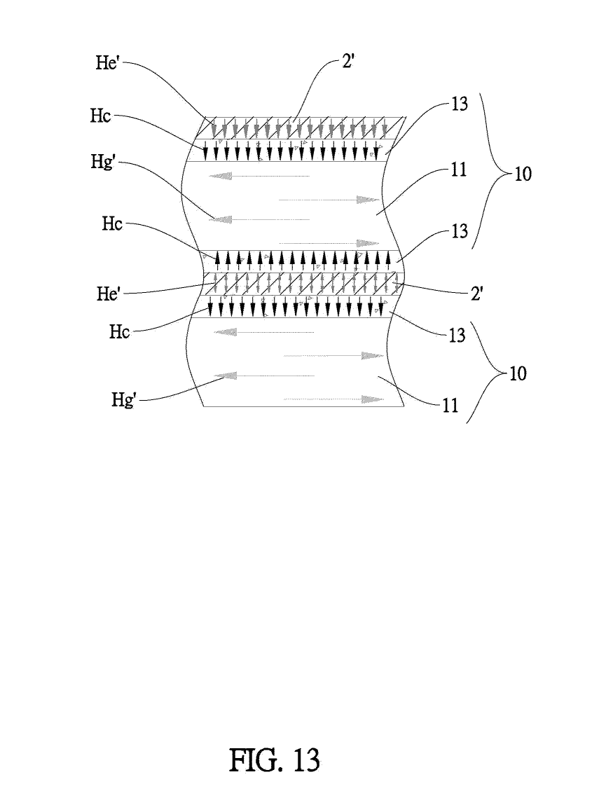

Please refer to FIG. 13, a seventh preferred embodiment of the invention is a structure of a “multilayer thermal conductivity circuit board” comprising two or more heat dissipation structure element 10 and cooper foil (circuit) 2′ that are composed and pressed together, thus to form the multilayer thermal conductivity circuit board.

While the invention has been described in terms of preferred embodiments, those skilled in the art will recognize that the invention can be practiced with modifications within the spirit and scope of the appended claims.

What is claimed is:

1. A heat dissipation structure for an electronic device that is adhered on the electronic device to conduct heat dissipation wherein the heat dissipation structure comprises at least one heat dissipation structure element; each of the at least one heat dissipation structure element includes a high thermal conductivity material element and a thermal conductivity insulating medium which is disposed between the high thermal conductivity material element and an outside area to provide insulation and thermal conductivity function; and the thermal conductivity insulating medium is composed of a combination of ceramic and polymers.

2. The heat dissipation structure as claimed in claim 1, wherein the material of the high thermal conductivity material element can be graphite.

3. The heat dissipation structure as claimed in claim 1, wherein the material of the high thermal conductivity material element can be metal.

4. The heat dissipation structure as claimed in claim 1, wherein the heat dissipation structure element can be composed of the high thermal conductivity material element having the thermal conductivity insulating medium joined onto its one side.

5. The heat dissipation structure as claimed in claim 1, wherein the heat dissipation structure element can be composed of the high thermal conductivity material element having the thermal conductivity insulating medium joined onto its both sides.

6. The heat dissipation structure as claimed in claim 1, wherein the heat dissipation structure element can be composed of the high thermal conductivity material element having the thermal conductivity insulating medium joined onto its one side and the insulating medium joined onto its other side.

7. The heat dissipation structure as claimed in claim 1, wherein the heat dissipation structure can be composed of one heat dissipation structure element.

8. The heat dissipation structure as claimed in claim 1, wherein the heat dissipation structure can be composed of two or more heat dissipation structure elements.

9. The heat dissipation structure as claimed in claim 1, wherein the adhesive medium can be disposed between the heat dissipation structure and the electronic device.

10. The heat dissipation structure as claimed in claim 1, wherein the heat dissipation structure and the electronic device can be joined to each other through the self adhesion of the heat dissipation structure.
